(19) United States
(12) Patent Application Publication
(10) Pub. No.: US 2003/0189456 A1
(43) Pub. Date: Oct. 9, 2003

(54) TTl controller system for one or more devices and a method thereof

(76) Inventors: Thomas H. Foster, Rochester, NY (US); David L. Conover, Rochester, NY (US); Jarod C. Finlay, Philadelphia, PA (US)

Correspondence Address: Gunnar G. Leinberg, Esq., NIXON PEABODY LLP, Clinton Square, P.O. Box 31051, Rochester, NY, 14603-1051, US

(21) Appl. No.: 10/338,948

(22) Filed: Jan. 8, 2003

Related U.S. Application Data
(60) Provisional application No. 60/346,566, filed on Jan. 8, 2002.

(51) Int. Cl. H03K 17/296

(52) U.S. Cl. 327/393

(57) ABSTRACT

A TTL controller system includes at least one timer system that generates a timing signal and at least one trigger system coupled to the at least one timer system and to each of the devices. The trigger system in response to the timing signal triggers with a trigger signal at least one operation in at least one of the devices. A time period for executing the at least one operation in at least one of the devices is adjustable.

The present invention claims the benefit of U.S. Provisional Patent Application Serial No. 60/346,566, filed Jan. 8, 2002, which is hereby incorporated by reference in its entirety. This invention was developed with government funding under National Institute of Health Grant No. CA68409. The U.S. Government may have certain rights.

### FIELD OF THE INVENTION

This invention relates generally to control systems and methods and, more particularly, to a transistor-transistor logic (TTL) controller system for one or more devices and a method thereof.

### BACKGROUND OF THE INVENTION

A variety of different types of systems have devices or components whose operation needs to be controlled and synchronized with the operation of other devices or components. Typically, some type of computer system which executes programmed instructions is used to control and synchronize the operations of these devices. Unfortunately, these types of control systems are difficult and expensive to implement.

### SUMMARY OF THE INVENTION

A system in accordance with embodiments of the present invention includes at least one timer system that generates a timing signal and at least one trigger system coupled to the at least one timer system and to each of the devices. The trigger system in response to the timing signal triggers with a trigger signal at least one operation in at least one of the devices. A time period for executing the at least one operation in at least one of the devices is adjustable.

A method in accordance with embodiments of the present invention includes generating at least one timing signal and triggering with at least one trigger signal at least one operation in at least one of the devices in response to the at least one timing signal. A time period for executing the at least one operation in the at least one of the devices is adjustable

The present invention can automatically and sequentially control a variety of different types of standard TTL-triggered devices in a simple, flexible, easy to use and low-cost manner. Additionally, the present invention can easily adjust the duration of “on-time” of each of the devices, as well as the delay between sequential steps. Since standard TTL signals are used for both input and output control, the present invention can be readily interfaced with any TTL-compatible device making it useful for many automated TTL-triggered applications. The present invention can be readily modified to interface with complimentary metal oxide semiconductor (CMOS)-based equipment. Further, the present invention can easily be modified in a modular fashion to control as many devices as desired. The present invention also has a simple “corner-cube” design that allows any one of its six panels to be removed independently of the others to allow for easy internal access for modification or troubleshooting.

### BRIEF DESCRIPTION OF THE DRAWINGS

FIG. 1A is a block diagram of a TTL controller system coupled to a photodynamic therapy fluorescence/reflectance system in accordance with these exemplary embodiments of the present invention;

FIG. 1B is a view of another side of the TTL controller system shown in FIG. 1A;

FIG. 2A is a front view of a housing for the TTL controller system shown in FIG. 1A;

FIG. 2B is a side view of the housing for the TTL controller system shown in FIG. 1A;

FIG. 2C is a front view of a housing for the TTL controller system shown in FIG. 1A;

FIGS. 3-5 are circuit diagrams of the TTL controller system shown in FIGS. 1A-1B in accordance with embodiments of the present invention with representative signals during use of the TTL controller system;

FIG. 6 is a circuit diagram of a diode detector amplifier for the photodynamic therapy fluorescence/reflectance system in this example;

FIG. 7 is a circuit diagram of a window comparator for the photodynamic therapy fluorescence/reflectance system in this example;

FIG. 8 is a circuit diagram of a speaker driver for the photodynamic therapy fluorescence/reflectance system in this example;

FIG. 9 is a flow chart of a method of using a TTL controller system for a device in accordance with embodiments of the present invention; and

FIGS. 10A and 10B are timing diagrams for a detailed controller in accordance with one embodiment of present invention.

### DETAILED DESCRIPTION

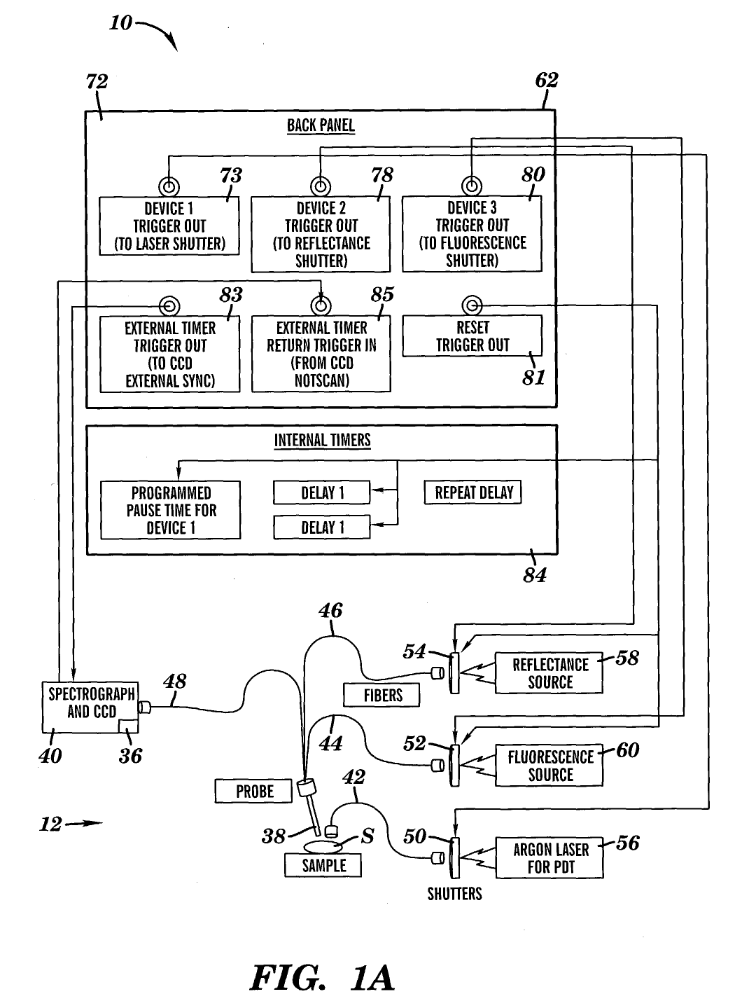

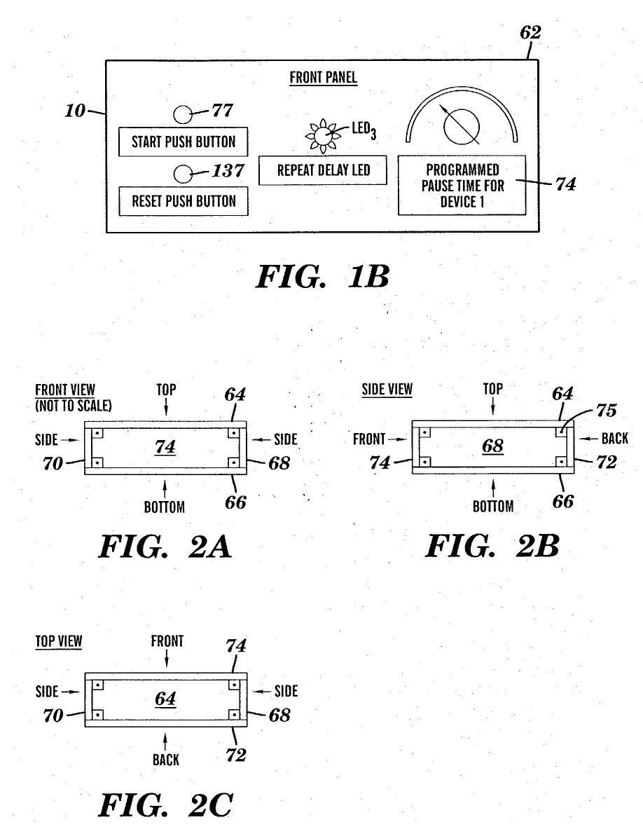

A TTL controller system 10 in accordance with embodiments of the present invention in a photodynamic therapy fluorescence/reflectance system 12 for analyzing a sample S is illustrated in FIGS. 1A-5. The TTL controller system 10 includes a starting device 14, trigger devices 16, 18, 20, 22, 24, 26, and 28, a pause device 30, delay devices 32, and 34, and 35 and reset device 37 although the TTL controller system 10 can comprise other types and numbers of components. The present invention can automatically and sequentially control a variety of different types of standard TTL-triggered devices in a simple, flexible, easy to use and low-cost manner.

Referring to FIGS. 1A-1B, in this exemplary embodiment, the photodynamic therapy system 12 includes a probe 38, a standard TTL-compatible charge-coupled device camera controller that captures the spectrum of light imaged through a grating spectrograph (spectrograph and CCD) 40, optical fibers 42, 44, 46, and 48, shutters 50, 52, and 54, a laser source 56, a reflectance source 58, a fluorescence excitation source 60, and the TTL controller system 10, although the photodynamic therapy system 12 can include other types and numbers of components. In the spectrograph and CCD 40, the CCD captures the spectrum of light imaged through a grating spectrograph. The spectrograph and CCD 40 also act as the external timer 36 for the shutters for the reflectance source 58 and fluorescence source 60.

In this particular embodiment, the probe 38 is positioned over a sample S and is coupled to one end of optical fibers 44, 46, and 48. The other ends of the optical fibers 48, 46, and 44 are coupled to the spectrograph and CCD 40, the reflectance source 58, and the fluorescence source 60, respectively. One end of another optical fiber 42 is positioned adjacent to the sample S and the other end of the optical fiber 42 is coupled to the laser source 56. Shutters 54, 52, and 50 are positioned between the other end of optical fiber 46 and the reflectance source 58, the other end of optical fiber 44 and the fluorescence source 60, and the other end of optical fiber 42 and the laser source 56, respectively. The shutter 50 is coupled to the first trigger output 76, the shutter 54 is coupled to the second trigger output 78, and the shutter 52 is coupled to the second trigger output 80 from the TTL controller system 10. A variety of different types of TTL-controlled devices, such as solenoid shutters, or other types of devices can be used.

Referring to FIGS. 1A-5, the TTL controller system 10 includes a housing 62, starting device 14, trigger devices 16, 18, 20, 22, 24, 26, and 28, a pause device 30, and delay devices 32 and 34, although the TTL controller system 10 can comprise other types and numbers of components. By way of example only, in these embodiments the TTL controller system 10 is used to trigger standard TTL compatible shutters 50, 52, and 54, such as the Uniblitz shutters from Vincent Associates, Rochester, N.Y., for the laser source 56, reflectance source 58, and fluorescence source 60 in the photodynamic therapy system 12, although the TTL controller system 10 can be used to perform other functions by controlling other types and numbers of TTL-controlled devices.

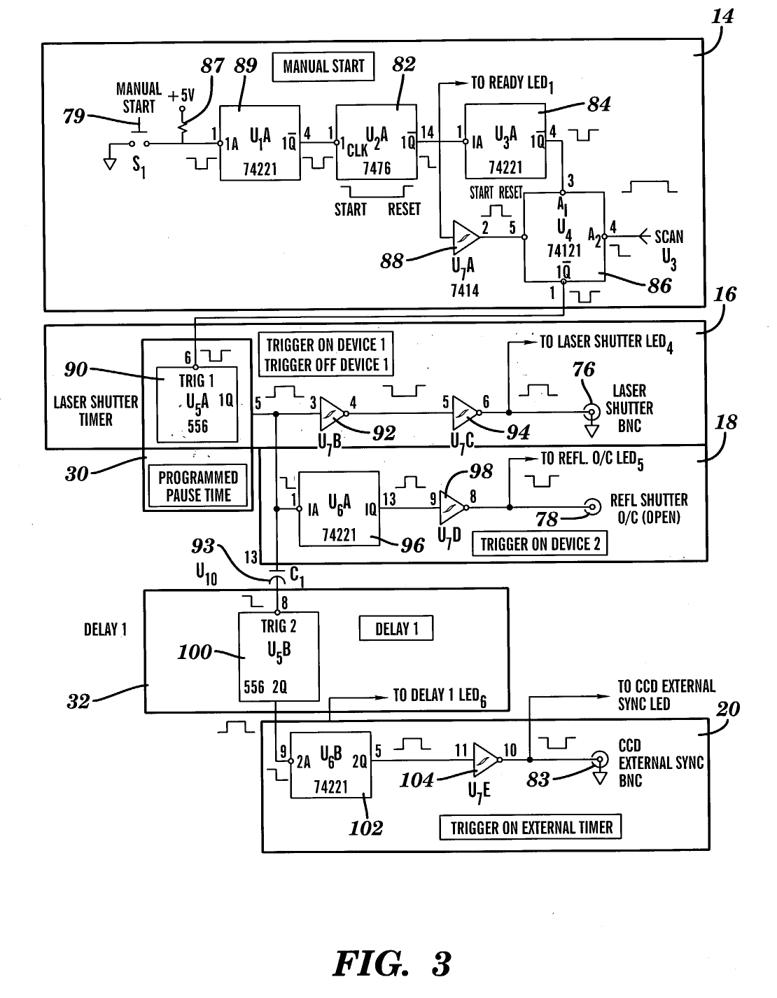

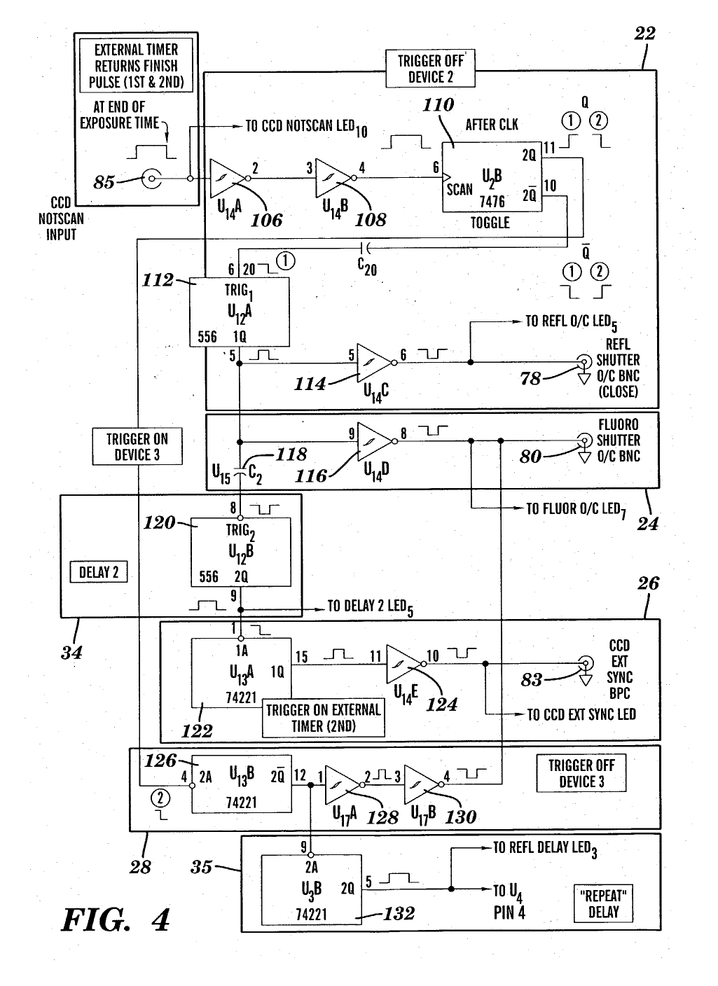

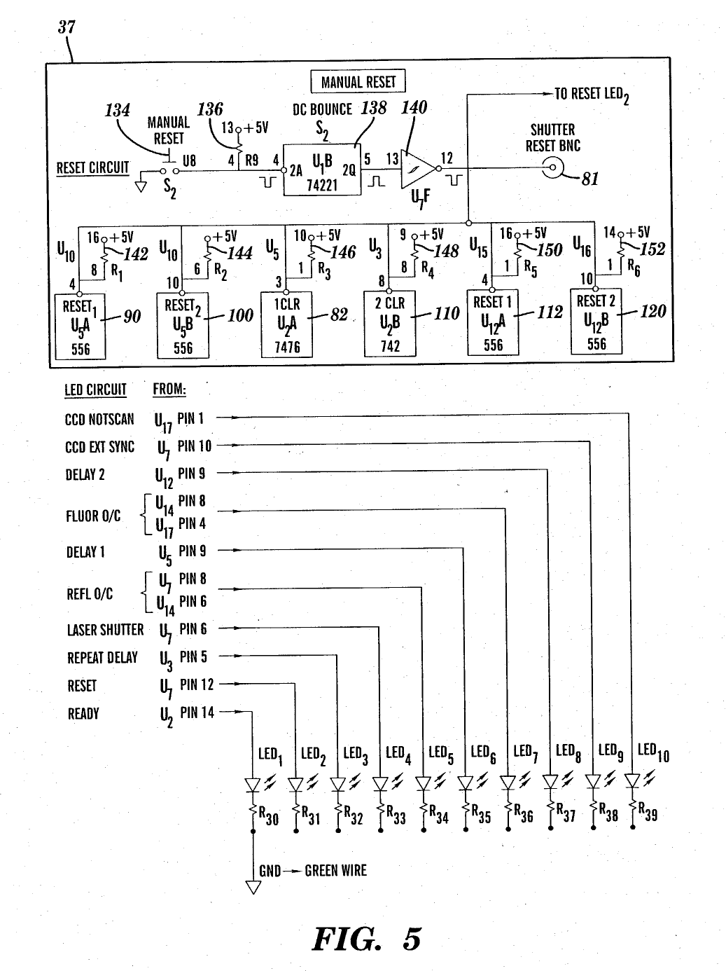

Referring more specifically to FIGS. 2A-2C, the housing 62 for the TTL controller system 10 is illustrated. In this particular embodiment, the housing comprises six panels 64, 66, 68, 70, 72, and 74 which are connected together along their edges by corner cubes 75 to form an enclosure. Any one of the six panels 64, 66, 68, 70, 72, and 74 can be removed independently of the others to allow for easy internal access for modification or troubleshooting. With this design, the housing 62 can be made to almost any size. The panels 64, 66, 68, 70, 72, and 74 can have different values of thickness and be made of various materials.

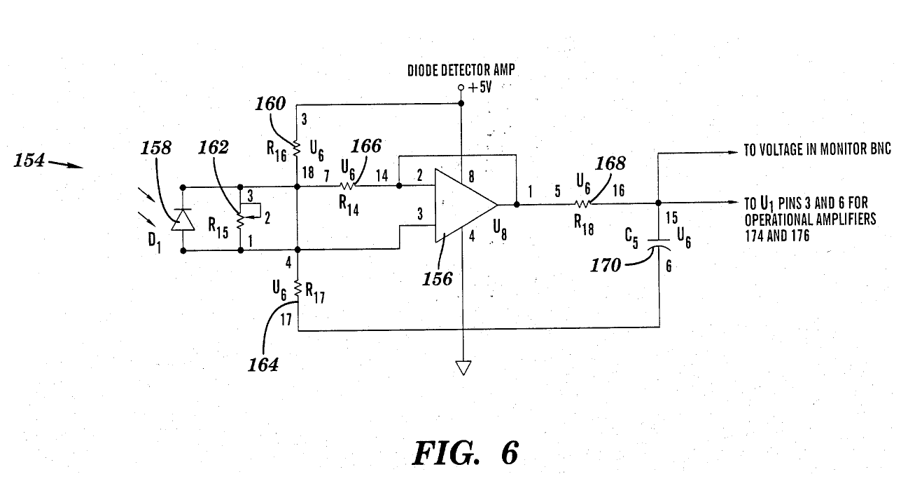

Referring to FIG. 3, the starting device 14 is used to initiate the operation of the system. In these embodiments, the starting device 14 includes a manual start switch 79, a resistor 87, dual one-shot circuits 89 and 84, a dual JK flip flop circuit 82, a single one-shot circuit 86, a Schmitt trigger hex inverter buffer circuit 88, although the starting device 14 can comprise other types and numbers of components. In this embodiment, the manual start switch 79 operated by start button 77 in FIG. 1B is normally open, although other arrangements can be used. The manual start switch 79 has one lead coupled to ground and another lead coupled to one end of a resistor 87 and to an input to a dual one-shot circuit 89. The other end of the resistor 87 is coupled to a five volt voltage source. An output from the dual one-shot circuit 89 is coupled to an input of the dual JK flip flop circuit 82. An output from the dual JK flip flop circuit 82 is coupled to ready LED₁ shown in FIG. 5, to an input of the dual one-shot circuit 84, and to an input to Schmitt trigger hex inverter buffer 88. The output from the dual one-shot circuit 84, the output from the Schmitt trigger hex inverter buffer circuit 88, and the output from dual one-shot circuit 132 are coupled to inputs to the single one-shot circuit 86.

The pause device 30 introduces a pause time which controls the duration between triggering the shutter 50 for the laser source 56 to open and close, although the pause device 30 can be used with other types of TTL-controlled devices. In these embodiments, the pause device 30 includes timer circuit 90, although the pause device 30 can comprise other types and numbers of components. The output from the single one-shot circuit 86 is coupled to in input of the timer circuit 90.

The trigger device 16 is used to trigger the shutter 50 for the laser source 56 to open and close, although the trigger device 16 can be used to control other TTL-controlled devices. In these embodiments, the trigger device 16 includes a pair of Schmitt trigger hex inverter buffer circuits 92 and 94, although the trigger device 16 can comprise other types and numbers of components. An input to one of the Schmitt trigger hex inverter buffer circuit 92 is coupled to an output from the timer circuit 90. The output of the Schmitt trigger hex inverter buffer circuit 92 is coupled to the input of the Schmitt trigger hex inverter buffer circuit 94. The output of the Schmitt trigger hex inverter buffer circuit 94 is coupled to output 73 which is coupled to the shutter 50 for the laser source 56 as shown in FIGS. 1A-1B and to laser shutter LED₄ shown in FIG. 5.

Trigger device 18 is used to trigger the shutter for the reflectance source 58 to open, although the trigger device 18 can be used to control other TTL-controlled devices. In these embodiments, the trigger device 18 includes a dual one-shot circuit 96 and a Schmitt trigger hex inverter buffer circuit 98, although the trigger device 18 can comprise other types and numbers of components. An input to the dual one-shot circuit 96 is coupled to the output from the timer circuit 90. The output of the dual one-shot circuit 96 is coupled to the input of the Schmitt trigger hex inverter buffer circuit 98. The output of the Schmitt trigger hex inverter buffer circuit 98 is coupled to output 78 which is coupled to the shutter 54 for the reflectance source 58 as shown in FIGS. 1A-1B and to reflectance shutter LED₅ shown in FIG. 5.

The delay device 32 is used to introduce a pre-determined delay that insures that the shutter 50 for the laser source 56 is fully closed and the shutter 54 for the reflectance source 58 is fully opened before reflectance data is taken, although the delay device 32 can be used to introduce a delay in other devices. In these embodiments, the delay device 32 includes a dual timer circuit 100, although the delay device 32 can comprise other types and numbers of components. An input of the dual timer circuit 100 is coupled to the output from the timer circuit 90. A capacitor 93 is coupled between timer circuits 90 and 100.

Trigger device 20 is used to trigger an external timer 36 in the spectrograph and CCD 40, although the trigger device 20 could be used to control other types of TTL-controlled devices. In these embodiments, the trigger device 20 includes a dual one-shot circuit 102 and a Schmitt trigger hex inverter buffer circuit 104, although the trigger device 20 can comprise other types and numbers of components. An input to the dual one-shot circuit 102 is coupled to the output from the dual timer circuit 100. The output of the dual one-shot circuit 102 is coupled to the input of the Schmitt trigger hex inverter buffer circuit 104. The output of the Schmitt trigger hex inverter buffer circuit 104 is coupled to the spectrograph and CCD 40 via the external timer output 83 as shown in FIGS. 1A-1B and to CCD external synchronization LED₉ shown in FIG. 5.

Referring to FIG. 4, the trigger device 22 is used to trigger the shutter 54 for the reflectance source 58 to close, although the trigger device 22 could be used to control other types of devices. In these embodiments, the trigger device 22 includes Schmitt trigger hex inverter buffer circuits 106, 108, and 114, capacitor 111, and dual timer circuits 110 and 112, although the trigger device 22 can comprise other types and numbers of components. The input to the Schmitt trigger hex inverter buffer circuit 106 is coupled to the input 85 from the external timer 36 in the spectrograph and CCD 40. A trigger signal from the external timer 36 initiates trigger device 22. An output of the Schmitt trigger hex inverter buffer circuit 106 is coupled to an input of the Schmitt trigger hex inverter buffer circuit 108. An output of the Schmitt trigger hex inverter buffer circuit 108 is coupled to an input of the flip flop circuit 110. An output of the flip flop circuit 110 is coupled to the input of the dual timer circuit 112. A capacitor 111 is coupled between flip flop circuit 110 and dual timer circuit 112. An output of the dual timer circuit 112 is coupled to an input of the Schmitt trigger hex inverter buffer circuit 114. An output of the Schmitt trigger hex inverter buffer circuit 114 is coupled to output 78 which is coupled to the shutter 54 for the reflectance source 58 as shown in FIGS. 1A-1B and to reflectance shutter LED₅ shown in FIG. 5.

Referring back to FIG. 4, the trigger device 24 is used to trigger the shutter 52 for the fluorescence source 60 to open, although the trigger device 24 can be used to control other types of TTL controlled devices. In these embodiments, the trigger device 24 includes a Schmitt trigger hex inverter buffer circuit 116 controlled by dual timer circuit 112, although the trigger device 24 can comprise other types and numbers of components. An input to the Schmitt trigger hex inverter buffer circuit 116 and a lead to capacitor 118 are coupled to an output from the dual timer circuit 112. An output from the Schmitt trigger hex inverter buffer circuit 116 is coupled to the output 80 which is coupled to shutter 52 for the fluorescence source 60 as shown in FIGS. 1A-1B and to fluorescence shutter LED₇ shown in FIG. 5.

The delay device 34 is used to introduce a delay between opening and closing the fluorescence shutter 52 and sending at trigger signal to the external timer 36, although the delay device 34 can be used to introduce a delay in other TTL-controlled devices. In these embodiments, the delay device 34 includes a dual timer circuit 120, although the delay device 34 can comprise other types and numbers of components. An input to the dual timer circuit 120 is coupled to a lead from capacitor 118.

The trigger device 26 sends a trigger pulse to output 83 for the spectrograph and CCD 40 to begin integrating light signals for fluorescence data and to begin an external timer 36 in the spectrograph and CCD 40 for the desired exposure time for fluorescence, although the trigger device 26 can be used to control other types of TTL-controlled devices. In these embodiments, the trigger device 26 includes a dual one-shot circuit 122 and a Schmitt trigger hex inverter buffer circuit 124, although the trigger device 26 can comprise other types and numbers of components. An input to the dual one-shot circuit 122 is coupled to an output from the dual timer circuit 120. An output from the dual one-shot circuit 122 is coupled to an input of the Schmitt trigger hex inverter buffer circuit 124. An output from the Schmitt trigger hex inverter buffer circuit 124 is coupled to the output 83 for the spectrograph and CCD 40 via the external timer 36 output as shown in FIGS. 1A-1B and to CCD external synchronization LED₉ shown in FIG. 5.

The trigger device 28 is used to trigger the shutter 52 for the fluorescence source 60 to close, although the trigger device 28 can be used to control other types of devices. In these embodiments, the trigger device 28 includes a dual one-shot circuit 126 and Schmitt trigger hex inverter buffer circuits 128 and 130, although the trigger device 28 can comprise other types and numbers of components. An input of the dual one-shot circuit 126 is coupled to an output from the dual timer circuit 110. An output of the dual one-shot circuit 126 is coupled to the input of the Schmitt trigger hex inverter buffer circuit 128. An output from the Schmitt trigger hex inverter buffer circuit 128 is coupled to an input of the Schmitt trigger hex inverter buffer circuit 130. An output from the Schmitt trigger hex inverter buffer circuit 130 is coupled to output 80 for the shutter 52 for the fluorescence source 60 as shown in FIGS. 1A-1B and to fluorescence shutter LED₇ shown in FIG. 5.

The delay device 35 is used to introduce a delay to provide an operator time to press the reset switch 134 shown in FIG. 5 to stop the operation, although the delay device 35 can be used to introduce a delay in other devices. If the reset switch or button 134 is not pressed within the delay time, then this whole sequence is repeated. In these embodiments, the delay device 35 includes a dual one-shot circuit 132, although the delay device 35 can comprise other types and numbers of components. An input to the dual one-shot circuit 132 is coupled to an output from the dual one-shot circuit 126. An output from the dual one-shot circuit 132 is coupled to a repeat delay LED₃ as shown in FIG. 5 and to one-shot circuit 86.

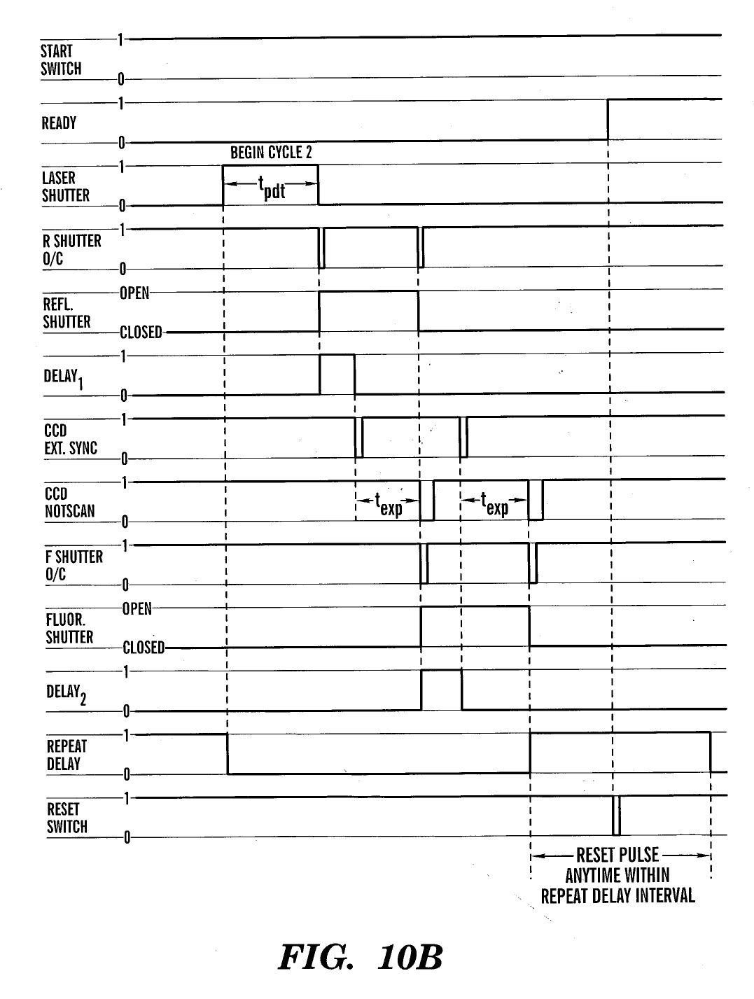

Referring to FIG. 5, the reset device 37 is used to stop the operations of opening and closing the shutters 50, 52, and 54 and to reset the system 10, although the reset device 37 can be used to control other functions. The reset device 37 includes reset switch 134, resistor 136, a dual one-shot circuit 138, a Schmitt trigger hex inverter buffer circuit 140, and resistors 142, 144, 146, 148, 150, and 152, although the reset device 37 can comprise other types and numbers of components. In these embodiment, the reset switch 134 is normally open, although other arrangements can be used. The reset switch 134 operated by reset button 137 in FIG. 10 has one lead coupled to ground and another lead coupled to one end of a resistor 136 and to an input to the dual one-shot circuit 138. The other end of the resistor 136 is coupled to a five volt voltage source. An output from the dual one-shot circuit 138 is coupled to an input of the Schmitt trigger hex inverter buffer circuit 140. An output from the Schmitt trigger hex inverter buffer circuit 140 is coupled to reset LED₂, to the shutter reset output 81 shown in FIG. 1A which is coupled to the shutters 52 and 54 for the fluorescence and reflectance source 58 and 60, and to an input to the timer circuits 90, 100, 112, and 120 and dual JK flip flop circuits 82 and 110. One lead of resistor 142 is coupled to a five volt voltage source and the other lead is coupled to the clear input to the timer circuit 90. One lead of resistor 144 is coupled to a five volt voltage source and the other lead is coupled to the clear input to the dual timer circuit 100. One lead of resistor 146 is coupled to a five volt voltage source and the other lead is coupled to the clear input to the dual JK flip flop circuit 82. One lead of resistor 148 is coupled to a five volt voltage source and the other lead is coupled to the clear input to the dual JK flip flop circuit 110. One lead of resistor 150 is coupled to a five volt voltage source and the other lead is coupled to the clear input to the dual timer circuit 112. One lead of resistor 152 is coupled to a five volt voltage source and the other lead is coupled to the clear input to the dual timer circuit 120.

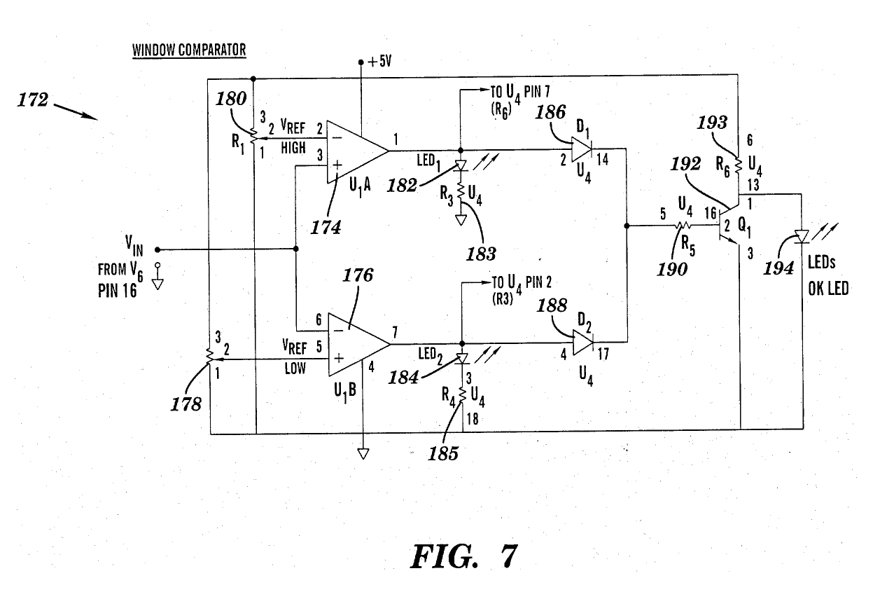

Referring to FIGS. 6-8, an external-voltage high-low limit monitor with “out-of-range” power warning indicators (audible and visual) in the TTL for the photodynamic therapy fluorescence/reflectance system 12 in this example is illustrated. This monitor outputs different visual (LED) and audible signals for high and low voltage warnings. The center value and high-low limits are adjustable and the unit has both an internal warning speaker and an external speaker connection for remote monitoring. In this particular application, this is used as a photodiode sensor-based laser power monitor to insure the laser beam from the laser source 56 remains constant throughout the experiment. In these embodiments, the warning levels are set to +/−2% of the target beam power for the laser beam from the laser source 56. A switch can deactivate the audible indicator.

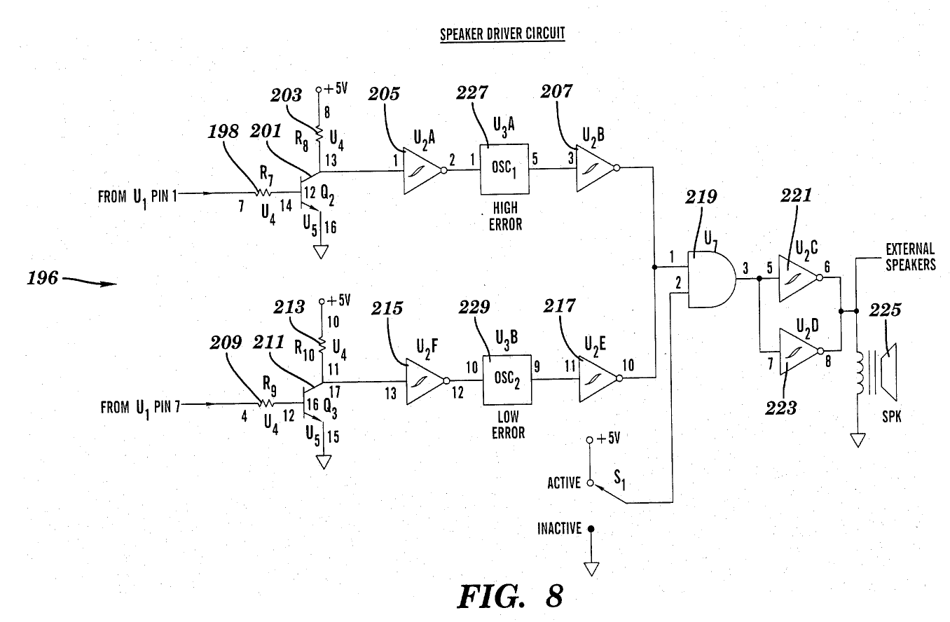

Referring more specifically to FIG. 6, a diode detector amplifier circuit 154 is shown. An operational amplifier 156 is coupled to a five volt voltage source and to ground. An output from the operational amplifier 156 is coupled back to an input to the operational amplifier and to one lead of a resistor 168. The other lead of the resistor 168 is coupled to voltage in monitor connector and to inputs to operational amplifiers 174 and 176 shown in FIG. 7. The input to the operational amplifier 156 is coupled to one lead of a resistor 166 and the other lead of the resistor 166 is coupled to a lead for resistors 160, 162, and 164. The other lead of resistor 160 is coupled to the five volt voltage source and the other lead of the resistor 164 is coupled to ground. The other lead of resistor 162 is coupled to the lead for the resistor 164 and a photodiode 158 is coupled in parallel with the resistor 162.

Referring to FIG. 7, a window comparator circuit 172 is shown. The window comparator 172 includes a pair of operational amplifiers 174 and 176 with one of the operational amplifiers 174 coupled to a five volt voltage source and the other one of the operational amplifiers 176 coupled to ground. The output of the one operational amplifier 174 is coupled to the anodes of two diodes 182 and diode 186 and the output of the other operational amplifier 176 is also coupled to the anodes of LED 184 and diode 188. The cathode of one LED 182 is coupled to a resistor 183 which is coupled to ground and the cathode of LED 184 is also coupled to a resistor 185 which is coupled to ground. The cathode of diode 186 is coupled to the cathode of the other diode 188 and to one lead of a resistor 190. The other lead of the resistor 190 is coupled to the base of a transistor 192. A resistor 193 is coupled between the collector of the transistor 192 and the five volt voltage source and the emitter of the transistor 192 is coupled to ground. An anode of LED 194 is coupled to the collector of the transistor 192 and the cathode is coupled to the emitter of the transistor 192. Inputs to the operational amplifiers 174 and 176 are coupled to a Vᵢₙ from resistor 168 in FIG. 6. Another input to operational amplifier 174 is coupled to a variable resistor 180 which is coupled between the five volt voltage source and ground. Another input to operational amplifier 176 is coupled to a variable resistor 178 which is coupled between the five volt voltage source and ground.

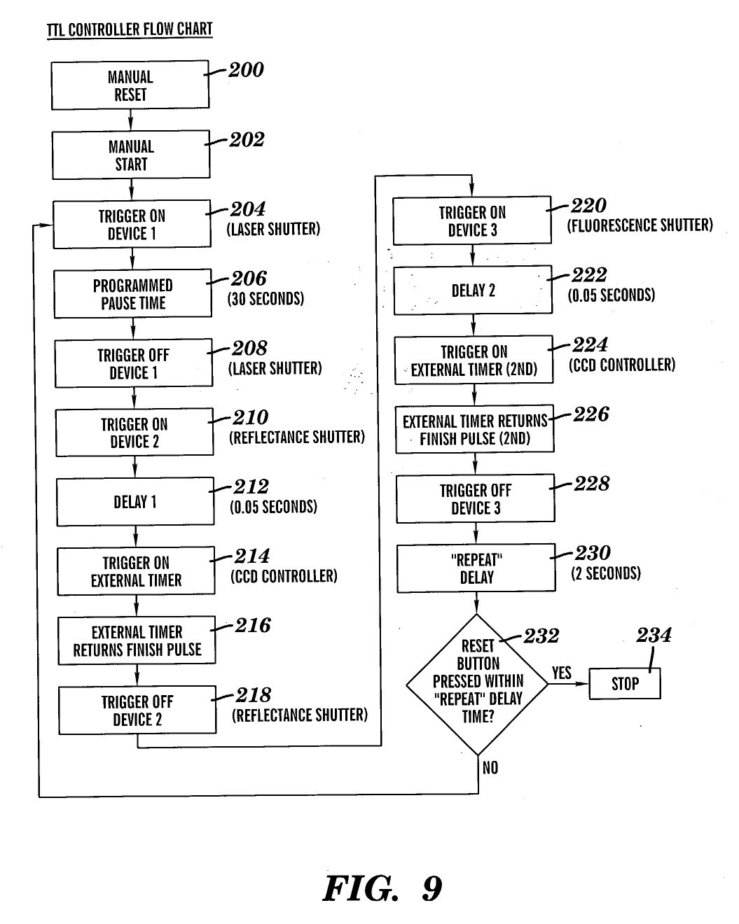

Referring to FIG. 8, a speaker driver circuit 196 is shown. The base of a transistor 201 is coupled to a resistor 198 which is coupled to U₁ pin 1, the collector of the transistor 201 is coupled to resistor 203 which is coupled to a five volt voltage source, and the emitter of the transistor 201 is coupled to ground. An input to a Schmitt trigger hex inverter buffer circuit 205 is coupled to the collector of the transistor 201. An output of the Schmitt trigger hex inverter buffer circuit 205 is coupled to an input to a dual oscillator circuit 227. An output of the oscillator circuit 227 is coupled to an input to a Schmitt trigger hex inverter buffer circuit 207.

The base of another transistor 211 is coupled to a resistor 209 which is coupled to U₁ pin 7, the collector of the transistor 211 is coupled to resistor 213 which is coupled to a five volt voltage source, and the emitter of the transistor 211 is coupled to ground. An input to a Schmitt trigger hex inverter buffer circuit 215 is coupled to the collector of the transistor 211. An output to the Schmitt trigger hex inverter buffer circuit 215 is coupled to an input to a dual oscillator circuit 229. An output to the dual oscillator circuit 229 is coupled to an input to a Schmitt trigger hex inverter buffer circuit 217.

Outputs from the Schmitt trigger hex inverter buffer circuits 207 and 217 are coupled to inputs to a quad and gate circuit 219. An output from the quad and gate circuit 219 is coupled to the inputs to dual Schmitt trigger hex inverter buffer circuits 221 and 223. The outputs of Schmitt trigger hex inverter buffer circuits 221 and 223 are coupled to a speaker 225 which is coupled to ground.

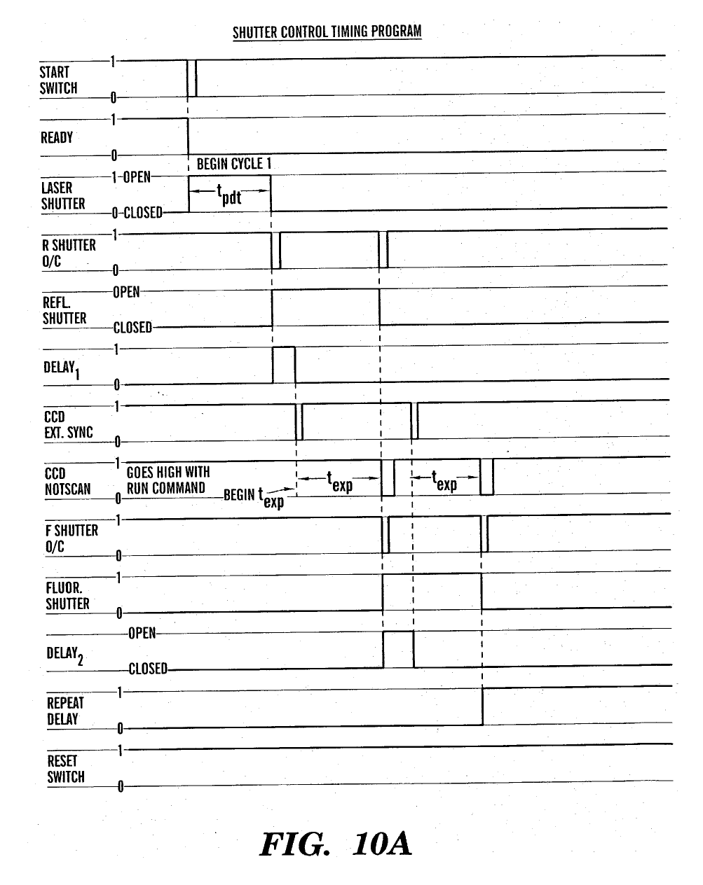

The operation of the TTL controller system 10 with a photodynamic therapy fluorescence/reflectance system 12 in accordance with embodiments of the present invention will be described with reference to FIGS. 1A, 1B, 3-5, 9, 10A, and 10B. Timing diagrams for the pulses discussed below are illustrated in FIGS. 10A and 10B. In these particular embodiments, the TTL controller system 10 is used to trigger, automatically and sequentially, three TTL compatible shutters 50, 52, and 54 in the photodynamic therapy system 12, although the TTL controller system 10 can be used to control other types and numbers of TTL-controlled devices.

In step 200, depressing the reset switch 134 resets the TTL controller system 10. In these particular embodiments, depressing the reset switch 134 creates a low-going pulse to the dual one-shot circuit 138. In response to the low-going pulse, the dual one-shot circuit 138 outputs a high-going pulse to the Schmitt trigger hex inverter buffer circuit 140 and then a valid logic low goes to reset inputs of timer circuits 90, 100, 112, and 120 and to dual JK flip flop circuit 82 and 110, to the shutter reset BNC connector output 81 which is coupled to the shutters 52 and 54 and to the reset LED₂. If the operator presses a “reset” button anytime during the sequence, the state of the “Ready” gate changes which terminates the sequence.

In step 202, depressing the manual start switch 79 starts the operation in the TTL controller system 10. In these particular embodiments, depressing the manual start switch 79 creates a low-going pulse to a dual one shot circuit 89. A falling edge from the pulse from the dual one-shot circuit 89 toggles the dual JK flip flop circuit 82 to a valid logic low which goes to the inputs of a dual one-shot circuit 84 and to the Schmitt trigger hex inverter buffer circuit 88. In response to the valid logic low, the dual one-shot circuit 84 and the Schmitt trigger hex inverter buffer circuit 88 respond with a valid logic high to trigger the single one-shot circuit 86.

In step 204, the shutter 50 for the laser source 56 is triggered by the trigger device 16 to an open position. In these particular embodiments, a falling edge of a pulse from single one-shot circuit 86 to an input of a timer circuit 90 produces a high-going pulse to Schmitt trigger hex inverter buffer circuit 92. In response to the high-going pulse, the Schmitt trigger hex inverter buffer circuit 92 inverts the pulse and outputs a low-going pulse to Schmitt trigger hex inverter circuit 94 which inverts the pulse and outputs a high-going pulse. The high-going pulse is output to trigger the shutter 50 for the laser source 56 to open and to turn on LED₄ to indicate that the laser shutter 50 is open. The laser beam from the laser source 56 passes along the optical fiber 42 and is directed on to the sample S.

In step 206, a pause device causes the shutter 50 for the laser source 56 to remain open for a programmed pause time, such as pause times of 0.1, 15, 30, 60, or 120 seconds by way of example. The 0.1 second exposure time is used for setup situations in this example. In these particular embodiments, the pause time is the time to wait for the falling edge of high-going pulse being output from the timer circuit 90. The pause time in the timer circuit 90 is adjustable.

In step 208, after the pause time is over, the trigger device 16 triggers the shutter 50 for the laser source 56 to close. In these particular embodiments, in response to the falling edge of the high-going pulse, the Schmitt trigger hex inverter buffer circuit 92 outputs a high-going pulse to Schmitt trigger hex inverter circuit 94 which inverts the pulse and outputs a low-going pulse. The low-going pulse is output to trigger the shutter 50 for the laser source 56 to close and to turn off LED₄ to indicate that the laser shutter 50 is closed. The laser beam from the laser source 56 is now blocked from the sample S.

In step 210, the trigger device 18 triggers the shutter 54 for the reflectance source 58 to open. In these particular embodiments, the falling edge of the high-going pulse from timer circuit 90 triggers dual one-shot circuit 96 to generate and output a high-going pulse to Schmitt trigger hex inverter buffer circuit 98. The high-going pulse causes the Schmitt trigger hex inverter buffer circuit 98 to deliver a low-going pulse to trigger the shutter 54 for the reflectance source 58 to open and to pulse LED₅ off and back on.

In step 212, a delay device 32 starts a first delay time period. The first delay time period insures that the shutter 50 for the laser source 56 is fully closed and the shutter 54 for the reflectance source 58 is fully opened before reflectance data is taken. A 0.05 second first delay time period is used, although the length of the delay is adjustable for the particular application. In these particular embodiments, the low-going pulse from timer circuit 90 triggers dual timer circuit 100 to produce a high-going pulse that lasts for the first delay time period. The high-going pulse from the dual timer circuit 100 is also received by the LED₆ which turns on while the high-going pulse is being received.

In step 214, at the end of the first delay time period, a trigger device 20 sends a trigger pulse to the spectrograph and CCD 40 to begin integrating light signals for reflectance data and to begin an external timer 36 in the spectrograph and CCD 40 for the desired exposure time for reflectance. An operator determines the appropriate exposure time for the spectrograph and CCD 40 before the start of the sequence. In these particular embodiments, a falling edge from the high-going pulse from the dual timer circuit 100 triggers the dual one-shot circuit 102 whose high-going pulse is buffered through the Schmitt trigger hex inverter circuit 104. The Schmitt trigger hex inverter circuit 104 sends a low-going pulse to an external timer 36 through output 83 in the spectrograph and CCD 40 to begin integrating light signals for reflectance data and to LED₉ to pulse the LED₉ off and back on.

In step 216, at the completion of the first exposure time for reflectance determined by the external timer 36 in the spectrograph and CCD 40, the spectrograph and CCD 40 sends a trigger pulse (“Not Scan”) back to input connector 85 in the TTL controller system 10. At the end of the external timer's routine, the external timer 36 returns a low-going logic level. Although an external timer 36 is shown in these embodiments, other timers, such as an internal timer in the TTL controller system 10, can also be included in the TTL controller system 10.

In step 218, the trigger device 22 triggers the shutter 54 for the reflectance source 58 to close. In these particular embodiments, the low-going pulse from the external timer 36 is sent to turn off an indicator LED₁₀ and to Schmitt trigger hex inverter buffer circuit 106 and then to Schmitt trigger hex inverter buffer circuit 108. This buffered low-going pulse triggers the dual JK flip flop circuit 110 to toggle which causes the \overline{2Q} output to go low. This low-going pulse triggers dual timer circuit 112 to generate a high-going pulse that is buffered by Schmitt trigger hex inverter buffer circuit 114. This low-going pulse is also sent to trigger the shutter 54 through output 78 for the reflectance source 58 to close and to pulse LED₅ off and back on.

In step 220, the trigger device 24 opens the shutter 52 for the fluorescence source 60 through output 80. In these particular embodiments, the high-going pulse from the dual timer circuit 112 is also sent to Schmitt trigger hex inverter buffer circuit 116 which delivers a low-going pulse to trigger the shutter 52 for the fluorescence source 60 to open and to pulse on the LED₇ off and back on.

In step 222, a delay device 34 starts a second delay time period. In these particular embodiments, the high-going pulse from the dual timer circuit 112 is also sent to dual timer circuit 120 through capacitor 118 causing a low-going pulse which in response produces a high-going pulse for a second delay time period. The second delay time period in the delay device 34 is adjustable. The high-going pulse from the dual timer circuit 120 is also sent to turn on the LED₈.

In step 224, at the end of the second delay time period, a trigger device 26 sends a trigger pulse to the spectrograph and CCD 40 through output 83 to begin integrating light signals for fluorescence data and to begin an external timer 36 in the spectrograph and CCD 40 for the desired exposure time for fluorescence. In these particular embodiments, at the completion of the second delay time period the high-going pulse from the dual timer circuit 120 goes low which triggers the dual one-shot circuit 122. The dual one-shot circuit 122 generates a high-going pulse which is buffered by the Schmitt trigger hex inverter buffer circuit 124 and which outputs via output 83 a low-going pulse to the external timer 36 in the spectrograph and CCD 40 to trigger the external timer 36 to start. The low-going pulse from the Schmitt trigger hex inverter buffer circuit 124 is also sent to pulse off and back on the LED₁₀.

In step 226, at the completion of the second exposure time for fluorescence determined by the external timer 36 in the spectrograph and CCD 40, the spectrograph and CCD 40 sends a low-going trigger pulse (“Not Scan”) back to output 85 of the TTL controller system 10. In these particular embodiments, the low-going trigger pulse from the external timer 36 is sent to turn off LED₁₀ and to Schmitt trigger hex inverter buffer circuit 106 then to Schmitt trigger hex inverter buffer circuit 108. This buffered low-going pulse triggers dual JK flip flop circuit 110 to toggle which causes the 2Q output in the dual JK flip flop circuit 110 to go low (it was set high on the first trigger).

In step 228, the trigger device 28 triggers the shutter for the fluorescence source 60 to close. In these particular embodiments, the low-going pulse from the 2Q output in the dual JK flip flop circuit 110 triggers dual one-shot circuit 126 to generate a low-going pulse that is buffered by Schmitt trigger hex inverter buffer circuit 128 and then by Schmitt trigger hex inverter buffer circuit 130. This low-going pulse is sent to trigger the shutter for the fluorescence source 60 to close and to pulse the LED₇ off and back on.

In step 230, a repeat delay period starts to provide an operator an opportunity to stop the operation of the photodynamic therapy system 12. A repeat delay period of about two seconds is used, although the length of the repeat delay period can be adjusted as necessary for the particular application. In these particular embodiments, the low-going pulse from the dual one-shot circuit 126 is also sent to the dual one-shot circuit 132 which generate a high-going pulse which stays high for the repeat delay period of time.

In step 232, the TTL controller system 10 determines if the reset switch 134 was closed by pressing reset button 137 during the repeat delay time period. If the reset switch 134 was closed, then the Yes branch is taken to step 234 where the operation stops. If the reset switch 137 was not closed, then the No branch is taken back to step 204 where the operation begins again as described herein.

Accordingly, as illustrated above the present invention can automatically and sequentially control a variety of different types of standard TTL-triggered devices in a simple, flexible, easy to use and low-cost manner. Because of the flexibility of the present invention, in the embodiments described above the duration of shutters 50, 52, and 54 being opened as well as the delay between sequential steps can be easily modified by changing component values. This allows the TTL controller system 10 to be readily adapted to other automated shutter applications. In general, the present invention's flexible design offers automatic and sequential control to any number of TTL-triggered devices.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations therefore, is not intended to limit the claimed processes to any order except as may be specified in the claims. Accordingly, the invention is limited only by the following claims and equivalents thereto.

What is claimed is:

1. A system for controlling one or more devices, the system comprising:
at least one timer system that generates a timing signal; and
at least one trigger system coupled to the at least one timer system and to each of the devices, wherein the trigger system in response to the timing signal triggers with a trigger signal at least one operation in at least one of the devices, wherein a time period for executing the at least one operation in at least one of the devices is adjustable.

2. The system as set forth in claim 1 wherein the at least one timer system comprises an external timing system, wherein an external timing signal from the external timing system triggers with a trigger signal at least one operation in at least one of the devices.

3. The system as set forth in claim 1 wherein the at least one trigger system is a TTL signal generator system.

4. The system as set forth in claim 1 further comprising a starting device coupled to the at least one timer.

5. The system as set forth in claim 1 further comprising a reset system coupled to the at least one timer.

6. The system as set forth in claim 1 further comprising two or more of the timer systems and two or more of the trigger systems, wherein the two or more trigger systems each trigger at least one operation in at least one of the devices sequentially.

7. The system as set forth in claim 6 wherein the two or more timer systems and two or more trigger systems are synchronized.

8. The system as set forth in claim 6 wherein at least one of the two timer systems comprises an external timing system, wherein the external timing signal from the external timing system sequentially triggers with a trigger signal at least one operation in at least one of the devices.

9. A method for controlling one or more devices, the method comprises:
generating at least one timing signal; and
triggering with at least one trigger signal at least one operation in at least one of the devices in response to the at least one timing signal, wherein a time period for executing the at least one operation in the at least one of the devices is adjustable.

10. The method as set forth in claim 9 wherein the timing signal is an external timing signal.

11. The method as set forth in claim 9 wherein the trigger signal is a TTL compatible signal.

12. The method as set forth in claim 9 further comprises starting the generating of the at least one timing signal.

13. The method as set forth in claim 9 wherein the generating and the triggering are carried out in an indefinite cycle.

14. The method as set forth in claim 13 further comprising resetting the generating of the at least one timing signal to stop the indefinite cycle.

15. The method as set forth in claim 9 further comprising generating two or more of the timing signals and triggering with two or more trigger signals, wherein the generating and the triggering are carried out sequentially.

16. The method as set forth in claim 15 wherein the two or more timing signals and two or more trigger signals are synchronized.

17. The method as set forth in claim 15 wherein at least one of the two timing signals is an external timing signal, wherein the external timing signal from the external timing system sequentially triggers with a trigger signal at least one operation in at least one of the devices.
